(19) United States
(12) Patent Application Publication
(10) Pub. No.: US 2024/0037294 A1
(43) Pub. Date: Feb. 1, 2024

(54) SIMULATION APPARATUS AND SIMULATION SYSTEM

(71) Applicant: KAWASAKI JUKOGYO KABUSHIKI KAISHA, Kobe-shi, Hyogo (JP)

(72) Inventors: Akinori TANI, Kobe-shi (JP); Hitoshi NARIAI, Kobe-shi (JP)

(73) Assignee: KAWASAKI JUKOGYO KABUSHIKI KAISHA, Kobe-shi, Hyogo (JP)

(21) Appl. No.: 18/023,758

(22) PCT Filed: Aug. 30, 2021
(86) PCT No.: PCT/JP2021/031659

§ 371 Date: Feb. 28, 2023

(30) Foreign Application Priority Data
Aug. 28, 2020 (JP) 2020-144512

(51) Int. Cl. G06F 30/20

(52) U.S. Cl. CPC G06F 30/20

(57) ABSTRACT

A simulator includes circuitry and a storage. The storage stores target operation data indicative of a series of target operations, and data relevant to a virtual robot model. The processing circuitry performs: causing the robot model to operate according to the target operation data; outputting image data of the operating robot model to a display; accepting an input of a change in a first operation that is operation of the robot model according to the target operation data and is displayed on the display; associating information indicative of a state of the robot model in a second operation, to which the change is reflected, with information on the first operation included in the target operation data; and storing the associated information in the storage. The circuitry outputs image data indicative of the second operation to the display, when causing the robot model to perform the first operation.

### CROSS-REFERENCE TO RELATED APPLICATION

This application claims the priority and the benefit to Japanese Patent Application No. 2020-144512 filed on Aug. 28, 2020 with the Japan Patent Office, the entire contents of which are incorporated herein as a part of this application by reference.

### TECHNICAL FIELD

The present disclosure relates to a simulation device and a simulation system.

### BACKGROUND ART

Conventionally, in order to design an industrial robot and its peripheral environment, a simulation on a computer apparatus is a till eel. For example, Patent Document 1 discloses a comprehensive management system which dynamically links a virtual robot development system for an offset robot with an articulated arm to an actual robot operating system. The actual robot operating system can receive a control command by the simulation from the virtual robot development system, and execute the simulation of a motion control of the offset robot. The actual robot operating system feeds back virtual operational information, such as an error etc. of the motion of the offset robot by the simulation to the virtual robot development system. By the simulation and the feedback, a control program is developed in the virtual robot development system.

### Reference Document(s) of Conventional Art

### Patent Document

[Patent Document 1] JP2007-260834A

### DESCRIPTION OF THE DISCLOSURE

For example, between operation of the actual offset robot and operation of a virtual model of the offset robot which is simulated in the virtual robot development system, a difference resulting from differences of the characteristics, such as the inertia and the rigidity of the offset robot, the viscosity of the joint(s) of the offset robot, and the reaction time of the drive(s) of the joint(s) may arise. It is difficult to thoroughly eliminate the characteristic differences. It is also difficult for the control program developed using the virtual operational information to thoroughly eliminate the characteristic differences, and therefore, it may cause a difference between operation which is performed by the model of the offset robot and operation which is performed by the actual offset robot. For example, the control program may not be able to make the model of the offset robot carry out the intended operation.

One purpose of the present disclosure is to provide a simulator and a simulation system which are capable of outputting an image of a virtual robot model indicating operation similar to an actual robot.

A simulator according to one aspect of the present disclosure includes processing circuitry and a storage. The storage stores target operation data indicative of a series of target operations, and data relevant to a virtual robot model. The processing circuitry includes a simulator functional part that causes the robot model to operate according to the target operation data, and outputs image data of the operating robot model to a display and an information processing part that accepts an input of a change in a first operation that is operation of the robot model according to the target operation data and is displayed on the display as an image, associates information indicative of a state of the robot model in a second operation, that is operation to which the change is reflected, with information on the first operation included in the target operation data, and stores the associated information in the storage. The simulator functional part outputs image data indicative of the second operation to the display, when causing the robot model to perform the first operation.

### BRIEF DESCRIPTION OF DRAWINGS

FIG. 1 is a schematic view illustrating one example of a configuration of a simulation system according to an illustrative embodiment.

FIG. 2 is a plan view illustrating one example of a robot work area according to the illustrative embodiment.

FIG. 3 is a block diagram illustrating one example of a hardware configuration of a computer apparatus according to the illustrative embodiment.

FIG. 4 is a block diagram illustrating one example of a functional configuration of the computer apparatus in which a simulation device according to the illustrative embodiment is configured.

FIG. 5 is a block diagram illustrating one example of a functional configuration of a simulator functional part of the computer apparatus according to the illustrative embodiment.

FIG. 6 is a side view illustrating one example of a state of a first operation of each of a robot and a robot model on the same scale.

FIG. 7 is a side view illustrating one example of the state of the first operation of the robot model when a simulation is performed using corrected control program data.

FIG. 8A is a flowchart illustrating one example of operation of the simulation system according to the illustrative embodiment.

FIG. 8B is a flowchart illustrating one example of the operation of the simulation system according to the illustrative embodiment.

FIG. 8C is a flowchart illustrating one example of the operation of the simulation system according to the illustrative embodiment,

FIG. 9 is a schematic view illustrating one example of a configuration of a simulation system according to Modification 1 of the illustrative embodiment.

FIG. 10 is a schematic view illustrating one example of a configuration of a simulation system according to Modification 2 of the illustrative embodiment.

### MODES FOR CARRYING OUT THE DISCLOSURE

### Embodiment

Hereinafter, an illustrative embodiment of the present disclosure is described with reference to the drawings. Each embodiment which will be described below is to illustrate a comprehensive or concrete example. Further, among components in the following embodiments, components which are not described in the independent claims which indicate the top concept are described as arbitrary components. Moreover, each figure in the accompanying drawings is a schematic figure, and is not necessarily illustrated exactly. Further, in each figure, the same reference characters are assigned to substantially the same components, and therefore, redundant explanation may be omitted or simplified. Moreover, the term “device” in this specification and the claims may mean not only a sole device but also a system including devices.

### Configuration of Simulation System

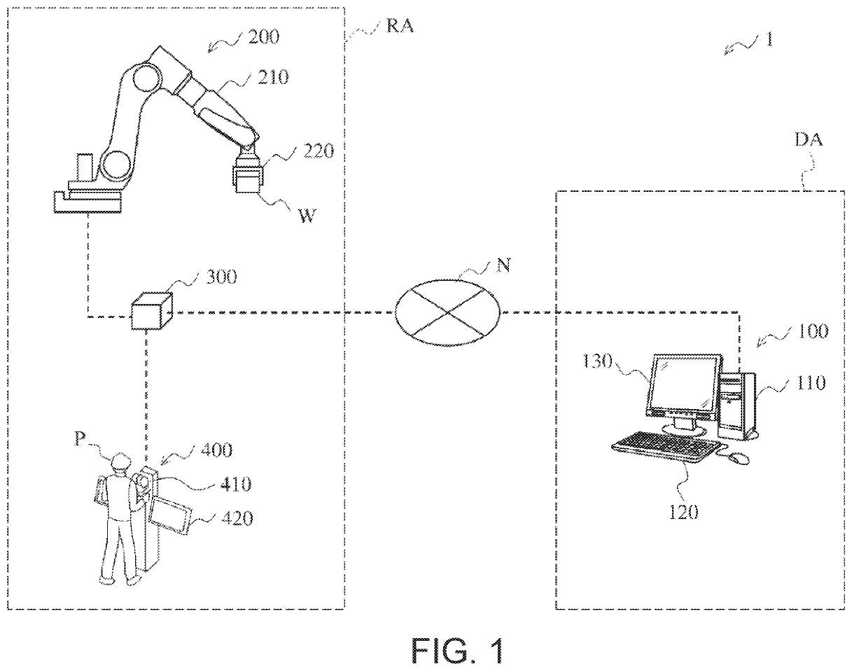

A configuration of a simulation system 1 according to the illustrative embodiment is described. FIG. 1 is a schematic view illustrating one example of the configuration of the simulation system 1 according to the illustrative embodiment. As illustrated in FIG. 1, the simulation system 1 includes a simulation computer 100, an actual robot 200, a robot controller 300, and an operation input/output (I/O) device 100. The robot controller 300 is one example of an actual machine controller.

Although not limited to this configuration, the robot 200 is an industrial robot and includes a robotic arm 210 and an end effector 220 in this embodiment. The robotic arm 210 includes at least one joint so that it has at least one versatility. The end effector 220 is configured to apply an action to an object W of a work, such as a workpiece. A tip end of the robotic arm 210 is configured so that the end effector 220 is attached thereto. The robotic arm 210 can freely change the position and the posture of the end effector 220. The robot 200 processes the object W using the robotic arm 210 and the end effector 220. Although in this embodiment the type of the robotic arm 210 is a vertical articulated type, it is not limited to this configuration but may be any type, and for example, it may be a horizontal articulated type, a polar coordinate type, a cylindrical coordinate type, or a Cartesian coordinate type.

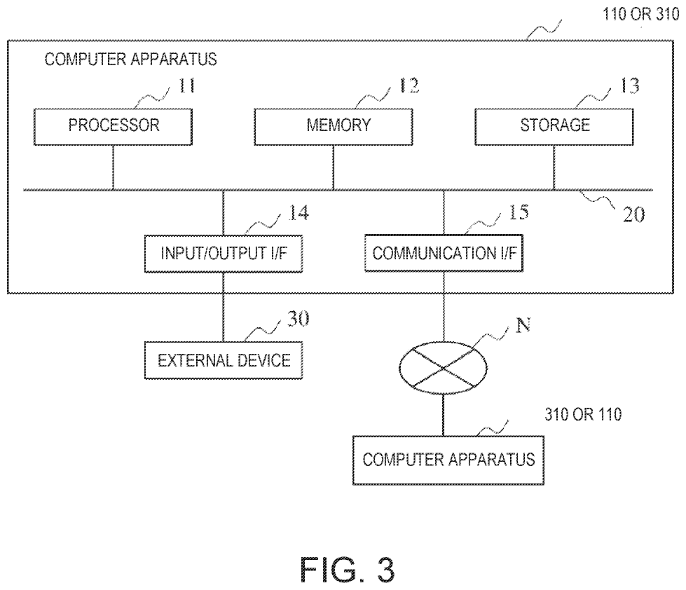

The robot controller 300 controls operation of the robot 200. The robot controller 300 processes a command, information, data, etc. which are inputted into the operation I/O device 400. The robot controller 300 controls operation of the robot 200 according to the command, information, data, etc. For example, the robot controller 300 controls supply of power etc. to the robot 200. The robot controller 300 outputs various commands, information, data, etc. to the operation I/O device 400. Such a robot controller 300 includes a computer apparatus 310 (see FIG. 3). The robot controller 300 may include electric circuitry for controlling electric power supplied to the robot 200, and an apparatus for controlling supply of a substance, such as paint, which is supplied to the end effector 220.

The robot controller 300 is connected with the robot 200 and the operation I/O device 400 via wired communications, wireless communications, or a combination of wired communications and wireless communications. The communications between these may be any kind of wired communications and wireless communications. In this embodiment the robot controller 300 and the operation I/O device 400 are disposed in a robot work area. RA where the robot 200 is disposed. At least either one of the robot controller 300 or the operation I/O device 400 may be disposed at a place different from the robot work area RA (for example, a remote place).

The operation device 400 includes an input device (inputter) 410 and a presentation device (presenter) 420. The input device 410 accepts an input of various commands, information, data, etc., and outputs it to the robot controller 300. The input device 410 may be any kind of known inputter, and, for example, it may be a device in which an input for operating the robot 200 is possible. The presentation device 420 perceptibly presents a user (hereinafter, also referred to as an “operator”) P the command, information, data, etc. received from the robot controller 300 etc. For example, the presentation device 420 may include a display, a speaker, etc.

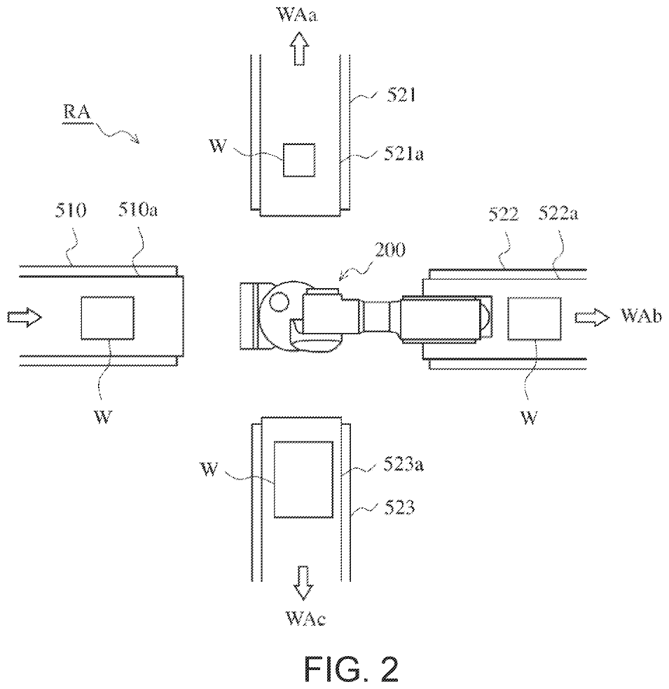

Although not limited to this configuration, in this embodiment, as illustrated in FIG. 2, a first conveying apparatus 510 which conveys the object W to the robot 200, and second conveying apparatuses 521, 522, and 523 which convey the object W which has been processed by the robot 200 to other areas WAa, WAb, and WAc, respectively, are disposed in the robot work area RA, as peripheral equipment of the robot 200. FIG. 2 is a plan view illustrating one example of the robot work area RA according to the illustrative embodiment.

In this embodiment, the robot 200 performs a line work in which it transfers the object W conveyed by the first conveying apparatus 510 to the second conveying apparatuses 521, 522, and 523 according to the transfer destination areas WAa, WAb, and WAc of the object W Although not limited to this configuration, the conveying apparatuses 510, 521, 522, and 523 are belt conveyors, which revolve endless ring-shaped conveyor belts 510a, 521a, 522a, and 523a in this embodiment. The robot controller 300 is configured to perform motion controls of the conveying apparatuses 510, 521, 522, and 523 collaboratively with the motion control of the robot 200, as an external axis control of the control of the robot 200.

As illustrated in FIG. 1, the simulation computer 100 is disposed in a designing operation area DA which is located at a place different from the robot work area RA. The simulation computer 100 is used in order to design a robot and its peripheral environment which are disposed in the robot work area RA. For example, the simulation computer 100 can build a virtual work area model including a virtual robot model, a virtual peripheral environment model, a virtual workspace model, etc. The peripheral environment model may include a virtual peripheral equipment model, a virtual peripheral structure model, a virtual object model which is a processing target object of the robot model, etc. For example, the simulation computer 100 is used for designing a line in a factory or a warehouse, and can build a virtual line etc.

Further, the simulation computer 100 can create control program data for causing the robot model, the peripheral equipment model, etc. to carry out a given operation automatically. The control program data may be data for automatically performing the entire given operation, or may be data for automatically performing a part of the given operation. The control program data is usable by the robot controller 300 which controls operation of the robot 200 etc. The robot controller 300 causes the robot 200 etc. to automatically perform the given operation according to the control program data. The simulation computer 100 may also cause the robot model, the peripheral equipment model, etc. to automatically perform the given operation according to the control program data. The simulation computer 100 offers an establishment of the work area model, and an offline simulation of the work area model.

For example, for the robot model the peripheral environment model, and the workspace model, three-dimensional models, such as three-dimensional CAD (Computer-Aided Design) models and three-dimensional CG (Computer Graphics) models may be used, or two-dimensional models may be used. The three-dimensional models and the two-dimensional models are configured to have characteristics corresponding to the characteristics of the actual robot, peripheral environment, and workspace. For example, the three-dimensional models and the two-dimensional models may have the shape and the dimension corresponding to the shape and the dimension of the actual machine, movable parts corresponding to the movable parts of the actual machine, and the characteristics of each part corresponding to the characteristics of each part of the actual machine. For example, the operating directions and the operating ranges of the movable parts of the three-dimensional model and the two-dimensional model may correspond to the operating directions and the operating ranges of the actual machine. For example, the impedance characteristics, such as the inertia, the rigidity, and the viscosity, of each part of the three-dimensional model and the two-dimensional model may correspond to the impedance characteristics of the actual machine. The weight characteristics and the weight distribution of each part of the three-dimensional model and the two-dimensional model may correspond to the weight characteristics and the gravity distribution of the actual machine.

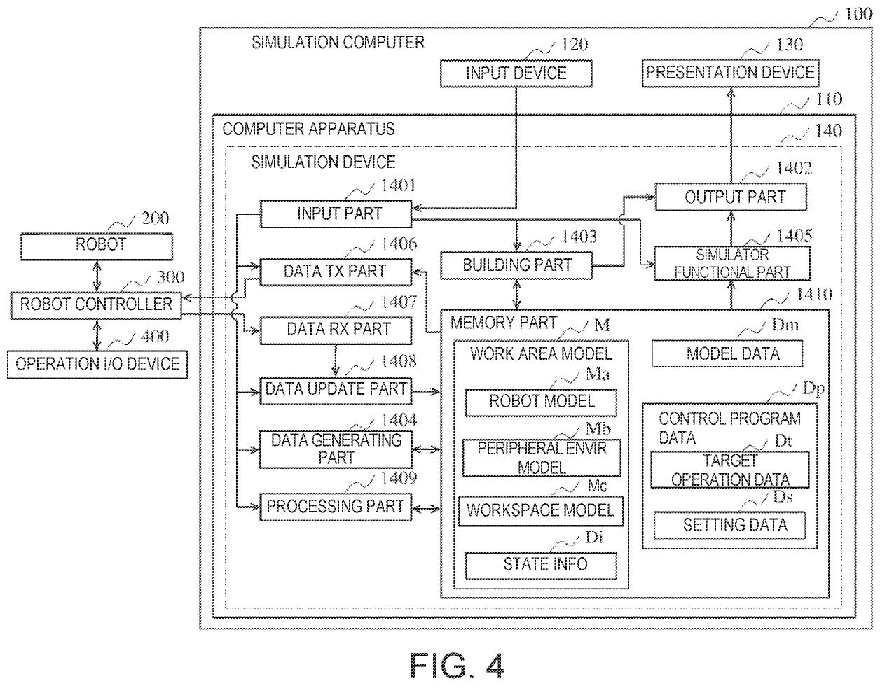

The simulation computer 100 includes a computer apparatus 110, an input device 120, and a presentation device 130. The configuration of the computer apparatus 110 is not limited in particular, and, for example, the computer apparatus 110 may be a personal computer, a workstation, a server, etc. A simulation device 140 (see FIG. 4) is configured inside the computer apparatus 110, and the function of the simulation device 140 is realized by the computer apparatus 110.

The input device 120 accepts inputs of various commands, information, data, etc., and Outputs them to the computer apparatus 110. For example, the input device 120 may include a known inputter, such as a lever, a button, a key, a keyboard, a touch panel, a touch display, a joystick, a motion capture, a camera, and a microphone. For example, the input device 120 may be a smart device, such as a smartphone and a tablet, a PDA (Personal Data. Assistant), or other terminals.

The presentation device 130 perceptibly presents a user (hereinafter, also referred to as a “designer”) of the simulation computer 100 the command, information, data, etc. received from the computer apparatus 110 etc. For example, the presentation device 130 may include a display, a speaker, etc. For example, the presentation device 130 displays an image, such as a virtual work area model. If the input device 120 includes a touch panel or a touch display, the input device 120 may also functionally serve as the presentation device 130. The presentation device 130 is one example of a display unit.

In this embodiment, the computer apparatus 110 is connected with the robot controller 300 so as to perform mutual data communications via wired communications, wireless communications, or a combination of wired communications and wireless communications. Although the communications between these may be any kind of wired communications and wireless communications, they are communications through a communication network N in this embodiment. In this case, the computer apparatus 110 and the robot controller 300 may be directly connected to the communication network N, or may be connected with the communication network N via a communication apparatus, such as a computer for communication.

For example, the computer apparatus 110 transmits the control program data to the robot controller 300. The robot controller 300 operates the robot 200 etc. according to the control program data. When the operation of the robot 200 etc. according to the control program data is corrected by the operator P, corrected control program data to which the correction is reflected is transmitted to the computer apparatus 110 by the robot controller 300, The designer can perform the establishment of the work area model and the simulation of the work area model using the simulation computer 100 and the information included in the corrected control program data.

The communication network N is not limited in particular, and, for example, it may include a LAN (Local Area. Network), a WAN (Wide Area Network), the Internet, or a combination of two or more of these. The communication network N may be configured to use a short-distance wireless communications, such as Bluetooth® and ZigBee®, a network private line, a private line of a communication enterprise, a PSTN (Public Switched Telephone Network), a mobile communications network, the Internet network, satellite communications, or a combination of two or more of these. The mobile communications network may use a 4th generation mobile communications system, a 5th generation mobile communications system, etc. The communication network N may include one or more networks.

The computer apparatus 110 and the robot controller 300 may be configured to input and output the information etc. to each other via a storage medium. For example, the storage medium may include a semiconductor-based or other IC (Integrated Circuit), an HDD (Hard Disk Drive), an HHD (Hybrid Hard Disk Drive), an optical disc, an ODD (Optical Disk Drive), a magneto-optical disc, an optical magnetism drive, an FDD (Floppy Disk Drive), a magnetic tape, an SSD (Solid State Drive), a RAM drive, a secure digital card or drive, or any other suitable storage media, or a combination of two or more of these.

One example of hardware configurations of the computer apparatus 110 of the simulation computer 100 and the computer apparatus 310 of the robot controller 300 are described. FIG. 3 is a block diagram illustrating one example of the hardware configurations of the computer apparatuses 110 and 310 according to the illustrative embodiment. As illustrated in FIG. 3, the computer apparatuses 110 and 310 each include a processor 11, a memory 12, a storage 13, an input/output IT (Interface) 14, and a communication I/F 15, as components. Although not limited to this configuration, these components are connected with each other via a bus 20, for example. The components included in the computer apparatuses 110 and 310 are not limited to the components described above, and, for example, components may be added corresponding to control targets and connection targets of the computer apparatuses 110 and 310.

The processor 11 and the memory 12 are included in processing circuitry or circuitry. The processing circuitry or the circuitry transmits to and receives from other devices a command, information, data, etc. The processing circuitry or the circuitry performs inputs of signals from various apparatus, and outputs of control signals to the respective control targets. The circuitry may include processing circuitry.

The memory 12 stores a program executed by the processor 11, various data, etc. The memory 12 may include a storage device, such as a semiconductor memory, including a volatile memory and a nonvolatile memory. Although not limited to this configuration, the memory 12 includes a RAM (Random Access Memory) which is a volatile memory and a ROM (Read-Only Memory) which is a nonvolatile memory in this embodiment.

The storage 13 stores various data. The storage 13 may include a storage device, such as a hard disk drive and an SSD.

The processor 11 forms a computer system together with the RAM and the ROM. The computer system may realize the function of the computer apparatus 110 or 310 by the processor 11 executing the program recorded on the ROM, while using the RAM as the work area. A part or all of the functions of the computer apparatuses 110 and 310 may be realized by the computer system described above, may be realized by hardware circuitry for exclusive use, such as electronic circuitry or an integrated circuit, or may be realized by a combination of the computer system and hardware circuitry described above. The computer apparatuses 110 and 310 may perform each processing by a centralized control by a sole computer apparatus, or may perform each processing by a distributed control by a collaboration of computer apparatuses.

Although not limited to this configuration, for example, the processor 11 includes a CPU (Central Processing Unit), an MPU (Micro Processing Unit), a GPU (Graphics Processing Unit), a microprocessor, a processor core, a multiprocessor, an ASIC (Application-Specific Integrated Circuit), an FPGA (Field Programmable Gate Array), etc., and each processing may be realized by a logical circuit or a dedicated circuit formed on an IC (Integrated Circuit) chip, an LSI (Large Scale Integration), etc. Processings may be realized by integrated circuits, or may be realized by a single integrated circuit.

The communication I/F 15 is an interface which connects the computer apparatus 110 or 310 with the communication network N, The communication I/F 15 performs communications with other computer apparatuses etc. via the communication network N, and has a function for transmitting and receiving data etc. The communication I/F 15 transmits data etc. to other computer apparatuses etc., receives data transmitted from other computer apparatuses etc., and transmits it to the processor 11, according to the command from the processor 11.

The input/output I/F 14 is an interface which connects the computer apparatus 110 or 310 with an external device 30. For example, although the external device 30 includes the input device 120, the presentation device 130, and the input device 410 and the presentation device 420 of the operation I/O device 400, it may include other devices. For example, the external device may be a drive (auxiliary memory) of a storage device or a storage medium. The input/output I/F 14 may integrally include an input I/F which accepts an input of data etc., and an output IX which outputs data etc., or may include the I/Fs separately.

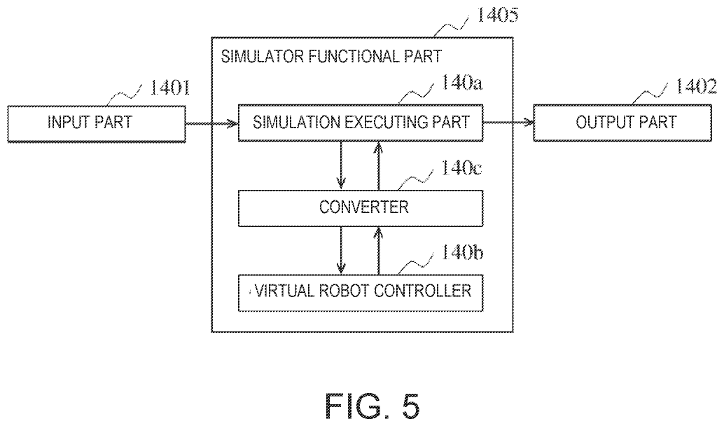

A functional configuration of the computer apparatus 110 is described. FIG. 4 is a block diagram illustrating one example of a functional configuration of the computer apparatus 110 in which the simulation device 140 according to the illustrative embodiment is configured. FIG. 5 is a block diagram illustrating one example of a functional configuration of a simulator functional part 1405 of the computer apparatus 110 according to the illustrative embodiment.

As illustrated in FIG. 4, the computer apparatus 110 includes the simulation device 140. For example, operation of the simulation device 140 may be realized by software installed in the computer apparatus 110, The processor 11 of the computer apparatus 110 operates as the simulation device 140 by executing the software described above.

The simulation device 140 includes an input part 1401, an output part 1402, a building part 1403, a data generating part 1404, the simulator functional part 1405, a data transmission part 1406, a data reception part 1407, a data update part 1408, a processing part 1409, and a memory part 1410, as functional components. Although the function of the memory part 1410 is realized by the storage 13, a part of the function of the memory part 1410 may be realized by the memory 12, The function of each functional component of the simulation device 140 excluding the memory part 1410 may be realized by the processor 11 and the memory 12 etc. The processing part 1409 is one example of an information processing part.

As illustrated in FIG. 5, the simulator functional part 1405 includes a simulation executing part 140a, a virtual robot controller 140b, and a converter 140c, as functional components.

As illustrated in FIG. 4, the input part 1401 accepts an input of the command, information, data, etc. from the input device 120 of the simulation computer 100, and sends it to each functional component inside the simulation device 140. The function of the input part 1401 may be realized by the input/output i/F 14 etc.

The output part 1402 outputs the command, information, data, etc. received from the building part 1403, the simulator functional part 1405, etc. to the presentation device 130 of the simulation computer 100. The function of the output part 1402 may be realized by the input/output i/F 14 etc.

The memory part 1410 stores various information, and makes read-out of the stored information possible. The memory part 1410 stores model data Din including data of a virtual component model which may serve as material of forming the virtual work area model. For example, the model data. Dm may include data of three-dimensional models of the component models, such as various virtual robot models, various virtual peripheral environment models, and various virtual workspace models.

The memory part 1410 stores data of a work area model M built by the building part 1403 etc. The memory part 1410 stores control program data Dp generated by the data generating part 1404 etc.

The building part 1403 builds a virtual work area model M. In detail, the building part 1403 sets a virtual three-dimensional space model according to the command, information, etc. inputted into the input device 120, and displays it on the presentation device 130. Further, the building part 1403 reads data of the three-dimensional models, such as the virtual workspace model, the virtual robot model, and the virtual peripheral environment model, which are specified via the input device 120, from the model data Dm of the memory part 1410. While the building part 1403 displays the virtual three-dimensional space model on the presentation device 130, it disposes each of the read-out three-dimensional models inside the three-dimensional space model according to the position, posture, size, etc. specified via the input device 120. The building part 1403 stores the three-dimensional space model where each three dimensional model is disposed in the memory part 1410 as the work area model M according to the command inputted into the input device 120. The work area model M includes a virtual robot model Ma, a virtual peripheral environment model Mb, a virtual workspace model Mc, etc. For example, the robot model Ma includes a robotic arm model Maa and an end effector model Mdb. The memory part 1410 may store various work area models M.

The data generating part 1404 generates the control program data Dp according to the command etc. inputted into the input device 120, and stores it in the memory part 1410. The data generating part 1404 may generate the control program data Dp for every work area model M, and may give discernment information, such as ID, in order to associate the control program data Dp with the work area model M.

The control program data Dp may include a control program for causing the robot model Ma and the peripheral environment model Mb to execute an operation inside the work area model M, execution data which is used by the control program for the execution, or both. Although not limited to this configuration, the control program described above is also a program for causing the actual robot and the actual peripheral environment corresponding to the robot model Ma and the peripheral environment model Mb to execute the operation in this embodiment.

The execution data includes target operation data Dt and setting data Ds. The setting data Ds may include data which is set to a model, and data which is set to a user environment. The data which is set to the model may include data which is set for every classification of the robot model Ma and the peripheral environment model Mb, data which is set for every classification of the end effector model Mab of the robot model Ma. etc. The data which is set to the user environment may include data which is set for every classification of an operation apparatus, such as the operation I/O device 400, for operating the actual robot and the actual peripheral environment corresponding to the robot model Ma and the peripheral environment model Mb, data which is set to a screen displayed on the operation apparatus, etc. The data generating part 1404 generates the setting data Ds according to the command, information, data, etc. which are inputted from the input device 120, the external device 30 other than the input device 120, or both of these.

The target operation data Dt is data indicative of a series of target operations which are performed by the robot model Ma and the peripheral environment model Mb inside the work area model M. The target operation data Dt may be data which is usable as teaching data for causing the actual robot and the peripheral equipment of the actual peripheral environment corresponding to the robot model Ma and the peripheral environment model Mb to perform the series of operations. The target operation data. Dt includes, for each operation included in the series of target operations, information on the position, posture, and force of each part of the robot model Ma, and information on the position and the posture of each part of the peripheral environment model Mb. The information on the position and the posture is information indicative of the three-dimensional position and posture inside the work area model M, and the information on the force is information indicative of the three-dimensional direction and magnitude of the force inside the work area model M.

For example, when the robot model Ma corresponds to the robot 200 illustrated in FIGS. 1 and 2, the robotic arm model Maa and the end effector model Mab of the robot model Ma are the virtual models of the robotic area 210 and the end effector 220 of the robot 200, respectively. The information on the position, posture, and force of each part of the robot model Ma may be information on the position, posture, and force of the end effector model Mab.

For example, when the peripheral environment model Mb is a virtual model of the conveying apparatuses 510, 521, 522, and 523 illustrated in FIG. 2, the information on the position and the posture of each part of the peripheral environment model Mb may correspond to the revolving positions of the conveyor belts 510a, 521a, 522a, and 523a, driving amounts of drives of the conveyor belts 510a, 521a, 522a, and 523a, or both of these.

The data generating part 1404 operates the robot model Ma and the peripheral environment model Mb according to the command, information, etc, inputted into the input device 120, detects the position, posture, and force of each part in each operation of the robot model Ma and the peripheral environment model Mb, and generates the target operation data Dt using information on the detected position, posture, and force. The target operation data Dt is time-series data in which the information on the position, the posture and the force are associated with an execution time.

When generating the control program, the data generating part 1404 may generate the control program of the robot model Ma and the peripheral environment model Mb using the target operation data Dt. The data generating part 1404 may generate the control program using the target operation data which the computer apparatus 110 received from other devices.

The data transmission part 1406 transmits the control program data Dp etc. which is stored in the memory part 1410 and is specified via the input device 120 to the robot controller 300 via the communication network N according to the command etc. inputted into the input device 120.

The data reception part 1407 receives control program data Dpa etc. from the robot controller 300 via the communication network N, and sends it to the data update part 1408. The control program data Dpa is control program data determined by the robot controller 300 based on the control program data Dp. For example, as a result of being executed by the robot controller 300, the control program data Dp may be corrected so that the operations of the actual robot 200 and the actual conveying apparatuses 510, 521, 522, and 523 become targeted operations. In this case, the control program data Dpa is corrected control program data Dp. When the correction of the control program data Dp is unnecessary, the control program data Dpa is non-corrected control program data Dp.

For example, in the robot work area RA, a trouble object may exist sideways of, above, etc, the robot 200. The impedance characteristics of the robot 200 may differ from the impedance characteristics of the robot model Ma. In such a case, the control program data Dp may be corrected using the robot controller 300 so that the robot 200 and the conveying apparatuses 510, 521, 522, and 523 perform the targeted operations.

The data update part 1408 stores in the memory part 1410 the control program data Dpa received from the data reception part 1407. The data update part 1408 may replace the control program data Dp, which corresponds to the control program data Dpa and is stored in the memory part 1410, by the control program data Dpa according to an update command inputted into the input device 120. The data update part 1408 may store in the memory part 1410 the control program data Dpa together with the control program data Dp, as second data corresponding to the control program data Dp, according to a save command inputted into the input device 120.

As illustrated in FIGS. 4 and 5, the simulation executing part 140a of the simulator functional part 1405 performs an operation simulation of the work area model M using the control program data Dp and the work area model M which are stored in the memory part 1410, according to the command etc. inputted into the input device 120, In detail, the simulation executing part 140a generates a target operation command for commanding the targeted operations of the robot model Ma and the peripheral environment model Mb according to the target operation data Dt. For example, the target operation command may include a position command and a force command. For example, the position command may include the positions and the postures of the movable parts of the end effector model Mab of the robot model Ma and the peripheral environment model Mb, the directions and the speeds of the positional changes, the directions and the speeds of the posture changes, etc. For example, the force command may include the magnitude, the direction, etc. of the force which is given to an object model Md by the end effector model Mab of the robot model Ma. The object model Md is a virtual model of the object W. The simulation executing part 140a sends the target operation command to the converter 140c.

The simulation executing part 140a receives a control command corresponding to the target operation command from the virtual robot controller 140b via the converter 140c, and operates the robot model Ma and the peripheral environment model Mb according to the control command. Further, the simulation executing part 140a generates image data of the robot model Ma and the peripheral environment model Mb which operate according to the control command, and outputs it to the presentation device 130 to display on the presentation device 130 the image corresponding to the image data. The designer who is the user of the simulation computer 100 is able to visually recognize the operations of the robot model Ma and the peripheral environment model Mb according to the control program data Dp.

The virtual robot controller 140b corresponds to the robot controller 300, and is configured to perform similar processing to the robot controller 300. The virtual robot controller 140b receives from the converter 140c a conversion operation command which is the target operation command after being processed by the converter 140c. The virtual robot controller 140b generates a control command for operating each part of the robot model Ma and the peripheral environment model Mb according to the conversion operation command, and sends it to the converter 140c.

For example, the virtual robot controller 140b may generate, based on the conversion operation command, a control command including command values, such as operation amounts, operation speeds, and operation torques of each joint of the robotic arm model Maa. and the operation part of the end effector of the robot model Ma, and each operation part of the peripheral environment model Mb.

The converter 140c converts, between the simulation executing part 140a and the virtual robot controller 140b, data outputted from one of them into data usable on the other.

Here, although not limited to this configuration, in this embodiment, the simulation device 140 is built regardless of the classification of the robot model which is the simulation target. The simulation executing part 140a is built as a part of the simulation device 140, together with the simulation device 140.

The virtual robot controller 140b is built according to the classification of the robot model of the simulation target. The robot controller 300 is generated according to the classification of the robot to be controlled. For example, the specifications of the robot controller 300 differ for different manufacturers of the robot to be controlled, and transceiving signals of the robot controller 300 differ for different manufacturers of the robot to be controlled. The specifications of the virtual robot controller 140b also differ for different corresponding robot controllers 300, and the input-′output signals of the virtual robot controller 140b also differ for different corresponding robot controllers 300. The specifications of the virtual robot controller 140b differ for different manufacturers of the actual robot corresponding to the robot model to be controlled.

The virtual robot controller 140b and the converter 140c may be incorporated into the simulation device 140 as software etc. Although the virtual robot controller 140b and the simulation executing part 140a cannot directly communicate the signal with each other, they can communicate the signal with each other via the converter 140c. Therefore, the versatility of the simulation device 140 improves. The simulation executing part 140a may be built corresponding to the virtual robot controller 140b so that the simulation executing part 140a and the virtual robot controller 140b can directly communicate the signal with each other.

As illustrated in FIG. 4, the processing part 1409 is configured to accept an input of a change in the operation of the robot model Ma which is indicated as an image displayed on the screen of the presentation device 130. In detail, the processing part 1409 can accept an input to change the operating state of the robot model Ma for an image of the robot model Ma displayed on the screen of the presentation device 130. The screen described above is a screen of the work area model M which is displayed on the presentation device 130 by the simulator functional part 1405 executing the simulation using the control program data Dp.

For example, the processing part 1409 processes to change a first image into a second image according to a command etc. of the change inputted into the input device 120 so that, in the first image indicative of a first operation among the operations of the robot model Ma, the first operation is changed into the second operation, and displays it on the screen of the presentation device 130. The second operation is operation to which the inputted change is reflected, and the second image is an image indicative of the robot model Ma in the second operation. For example, the second operation differs from the first operation. For example, the operation of the robot model Ma, such as the first operation and the second operation, may include a momentary operation which is indicated by an image of one frame, a series of operations which is indicated by images of frames and includes momentary operations, etc.

Further, the processing part 1409 associates the information indicative of the state of the robot model Ma in the second operation as state information Di with the information on the first operation included in the target operation data Dt, and stores it in the memory part 1410. The processing part 1409 may store the state information Di in the memory part 1410 as a part of the information on the work area model M. For example, the information indicative of the state of the robot model Ma in the second operation may include information indicative of the position, the posture, etc. of each part of the robot model Ma in the second operation, data of the second image indicative of the robot model Ma in the second operation, etc.

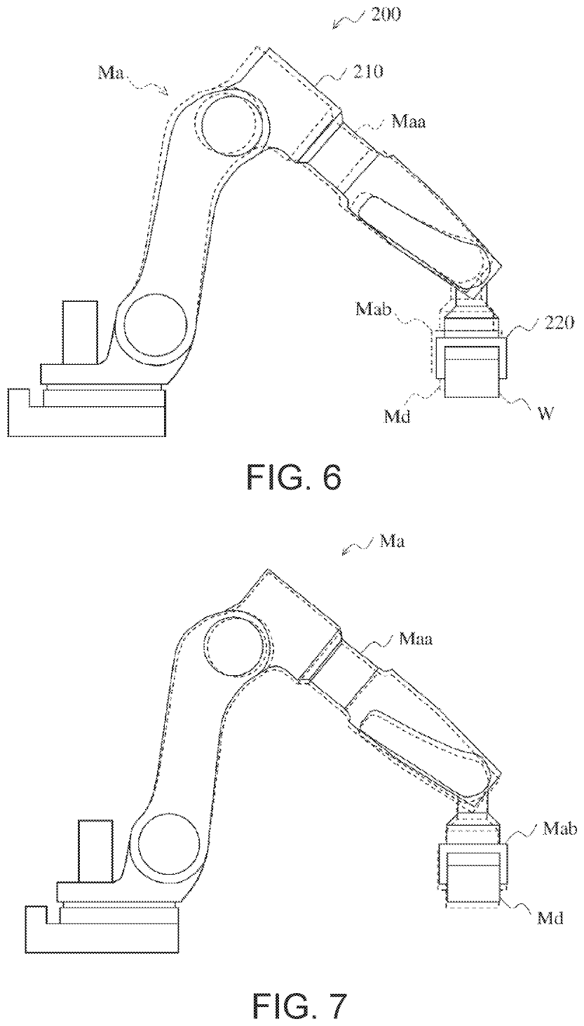

Here, it is very difficult to set the impedance characteristics of the robot model Ma so as to thoroughly match with the impedance characteristics of the robot 200. Further, the impedance characteristics of the robot 200 may be influenced by the gravity which acts on the robot 200, heat around the robot 200, etc. For example, in order to reduce the computational amount, the impedance characteristics may not be set to the robot model Ma. Thus, as illustrated in FIG. 6, when causing each of the robot 200 and the robot model Ma to perform the first operation which the object W and the object model Md are grasped according to the control program data Dp, a difference occurs in the deflection amount between the robotic arm 210 (a solid-line indication) of the robot 200 and the robotic arm model Maa (a broken-line indication) of the robot model Ma. In this example, since the rigidity of the robotic arm model Maa is larger than the rigidity of the robotic arm 210, the position of the end effector 220 is offset downwardly from the position of the end effector model Mab which is the target position. FIG. 6 is a side view illustrating one example of a state of the first operation of each of the robot 200 and the robot model Ma on the same scale.

Then, the operator P corrects the control program data Dp of the robot controller 300 so that, for the robot 200 which performs the first operation according to the control program data Dp, the position d the posture of the end effector 220 become in agreement with the target position and the target posture. For example, the operator P may move the end effector 220 to the target position and the target posture to teach the target position and the target posture to the robot controller 300. The robot controller 300 may correct the control program data Dp according to the teaching described above to generate corrected control program data. Dpa. The teaching method may be any kind of method.

As illustrated in FIG. 7, when the simulator functional part 1405 of the simulation device 140 performs a simulation using the corrected control program data Dpa, the position and the posture (solid-line indication) of the end effector model Mab of the robot model Ma may not agree with the target position and the target posture (broken-line indication). This originates in the difference in the impedance characteristics between the robot 200 and the robot model Ma. The target position and the target posture are the position and the posture when using the control program data Dp. In this example, since the rigidity of the robotic arm model Maa is larger than the rigidity of the robotic arm 210, the position of the end effector model Mab is offset upwardly from the target position. FIG. 7 is a side view illustrating one example of the state of the first operation of the robot model Ma when the simulation is performed using the corrected control program data Dpa.

Then, during the execution of the simulation using the corrected control program data Dpa, the designer moves the end effector model Mab to the target position and the target posture using the input device 120 on the screen of the presentation device 130 to cause the processing part 1409 to change the state of the robot model Ma from the first operation into the second operation. Further, the designer causes the processing part 1409 to store in the memory part 1410 information indicative of the state of the robot model Ma in the second operation.

After that, when executing the simulation using the corrected control program data Dpa, the simulator functional part 1405 requests the designer to select the image indicative of the operation of the robot model Ma. When causing the robot model Ma to perform the first operation according to the command accepted via the input device 120, the simulator functional part 1405 outputs the image data of the second image indicative of the second operation, or the image data of the first image indicative of the first operation.

For example, when a part of the work area model M, such as the model and the layout of the model, is changed, and when a new work area model is generated using the robot model Ma etc. of the work area model M, the simulator functional part 1405 can carry out a simulation of the operation of the work area model using the corrected control program data Dpa to which the characteristics of the actual robot 200 are reflected. Further, the simulator functional part 1405 can present the designer a comfortable image by outputting the image data of the second image indicative of the second operation in order to display the image of the first operation. Therefore, an accurate verification of the work area model using the simulation becomes possible.

### Operation of Simulation System

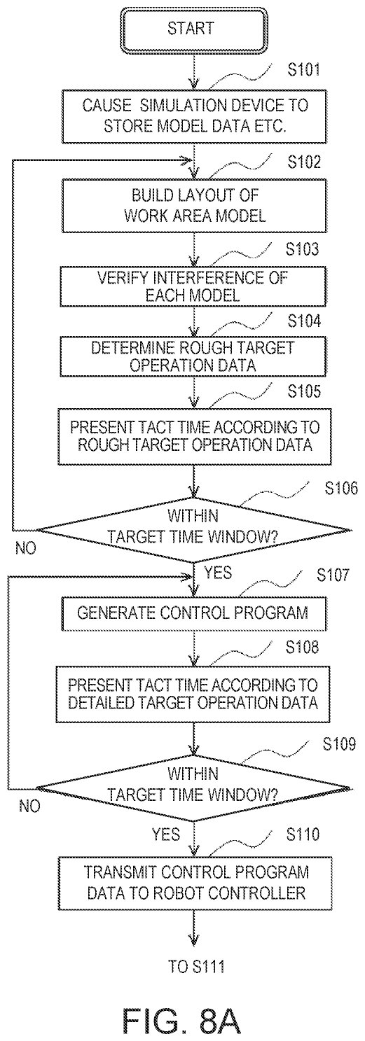

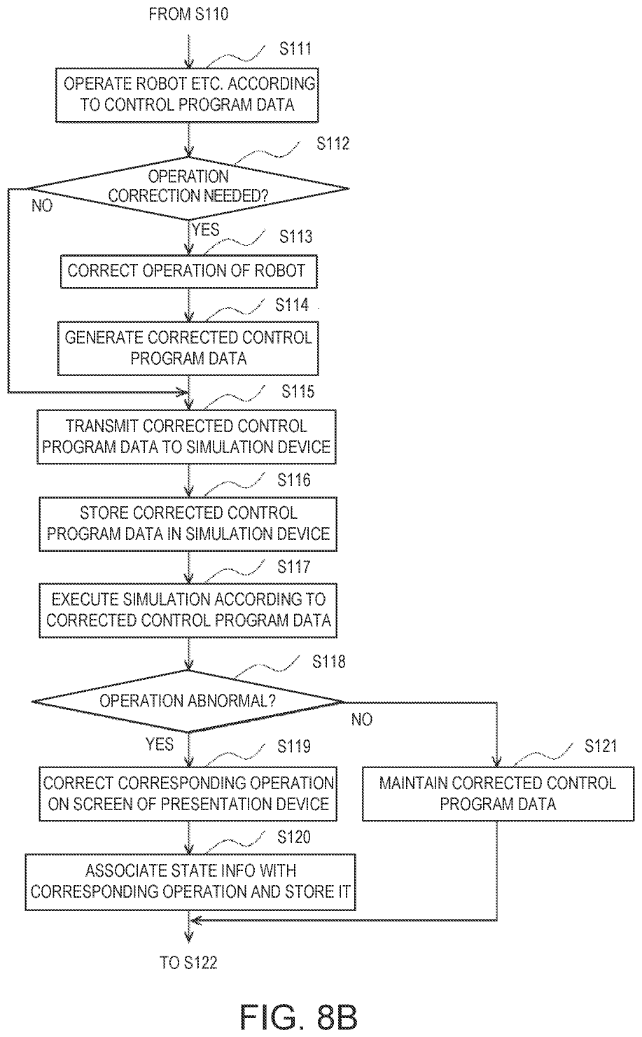

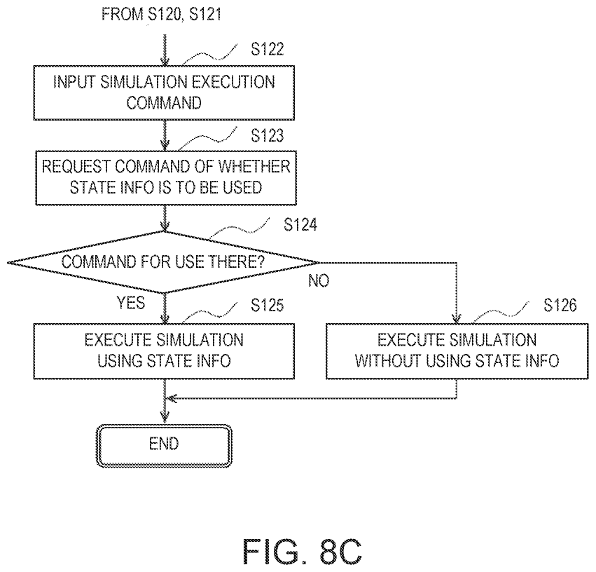

Operation of the simulation system 1 according to this embodiment is described, FIGS. 8A, 513, and 8C are flowcharts illustrating one example of the operation of the simulation system 1 according to the illustrative embodiment. In FIGS. 8A, 8B, and SC, processings from Step S101 to Step S110 are processings related to the generation of the work area model and the control program data. Processings from Step S111 to Step S115 are processings related to the verification of the control program data using the actual robot 200, and processings from Step S116 to Step S126 are processings related to the control program data after the verification.

As illustrated in FIGS. 8A, 8B, and SC, the designer of the designing operation area DA first causes the simulation device 140 of the computer apparatus 110 to store the model data Dm and the setting data Ds, via the input into the input device 120 (Step S101).

Next, the designer causes the simulation device 140 to build the layout of the work area model M via the input into the input device 120 (Step S102). In detail, the designer specifies the positions and the postures of the robot model Ma, the peripheral environment model Mb, and the workspace model Mc, and disposes each model, using the model data Dm, in the virtual three-dimensional space formed by the simulation device 140. The designer causes the simulation device 140 to store the work area model M in which each model is disposed.

Next, the designer verifies an interference of each model (Step S103). In detail, the designer inputs a command of an interference check into the input device 120. The simulation device 140 operates each model of the work area model M based on the setting data. Ds etc., and checks the existence of an interference of each model. When there is an interference, the simulation device 140 presents an interfering part etc. and the designer corrects the layout of the model via the input into the input device 120.

Next, the designer causes the simulation device 140 to determine and store rough target operation data of the robot model Ma and the peripheral environment model Mb of the work area model M (Step S104). In detail, the designer specifies rough target operations of the robot model Ma and the peripheral environment model Mb inside the work area model M via the input into the input device 120, and causes the simulation device 140 to generate the rough target operation data based on the target operation.

Next, the designer causes the simulation device 140 to present a tact time according to the rough target operation data (Step S105). In detail, the designer causes the simulation device 140 to execute the simulation of the work area model M according to the rough target operation data. The simulation device 140 presents the designer the tact time required for a series of operations according to the rough target operation data, and a target time window of the tact time.

If the tact time is deviated from the target time window No at Step S106), the designer commands the simulation device 140 to change the layout of each model, and causes it to repeat from Step S102 to Step S105.

If the tact time falls within the target time window (Yes at Step S106), the designer causes the simulation device 140 to generate the control program (Step S107). In detail, the designer causes the simulation device 140 to determine and store detailed target operation data Dt of the robot model Ma and the peripheral environment model Mb. The designer specifies the detailed target operation of the robot model Ma and the peripheral environment model Mb via the input into the input device 120, and causes the simulation device 140 to generate the detailed target operation data Dt based on the target operation. Further, the designer causes the simulation device 140 to generate the control program using the detailed target operation data Dt. The simulation device 140 stores the control program data Dp including the target operation data Dt and the control program.

Next, similarly to Step S105, the designer causes the simulation device 140 to present a final tact time according to the detailed target operation data (Step S108).

If the tact time is deviated from the target time window (No at Step S109), the designer commands the simulation device 140 to change the detailed target operation data. Dt, and causes it to repeat Steps S107 and S108.

If the tact time falls within the target time window (Yes at Step S109), the designer causes the simulation device 140 to transmit the control program data Dp to the robot controller 300 of the robot work area RA (Step S110). The robot controller 300 stores the received control program data Dp.

Next, the operator P of the robot work area RA causes the robot controller 300 to operate the robot 200 and the conveying apparatuses 510, 521, 522, and 523 according to the control program data Dp, via the input into the operation I/O device 400 (Step S111).

If the operation of the robot 200 needs to be corrected (Yes at Step S112) the operator P corrects the operation of the robot 200 (Step S113). If the operation of the robot 200 is not in agreement with the target operation, and if the robot 200 interferes with a surrounding object, the correction described above is required.

Next, the operator P causes the robot controller 300 to reflect the correction of the operation of the robot 200 to the control program data Dp, via the input into the operation I/O device 400, and causes it to generate the corrected control program data Dpa and store it (Step S114).

Next, the operator P causes the robot controller 300 to transmit the corrected control program data Dpa to the simulation device 140 of the computer apparatus 110 (Step S115). If the operation of the robot 200 does not need to be corrected (No at Step S112), the operator P causes the robot controller 300 to transmit the control program data Dp as the corrected control program data Dpa at Step S115.

Next, the simulation device 140 stores the received corrected control program data Dpa (Step S116).

Next, the designer of the designing operation area DA causes the simulation device 140 to execute the simulation according to the corrected control program data Dpa (Step S117).

If the operation of the robot model Ma displayed on the presentation device 130 is abnormal (Yes at Step S118), the designer causes the simulation device 140 to correct the first operation which is the corresponding operation of the robot model Ma to the second operation which is the targeted operation on the screen of the presentation device 130, by inputting a command into the input device 120 (Step S119).

Next, the simulation device 140 associates the information indicative of the state of the robot model Ma in the second operation, as state information Di, with the information on the first operation of the corrected control program data Dpa, and stores it (Step S120).

If the operation of the robot model Ma is not abnormal (No at Step S118), since there is no correction by the designer, the simulation device 140 maintains the stored corrected control program data Dpa as it is (Step S121).

Then, when the designer inputs an execution command of the simulation according to the corrected control program data Dpa into the input device 120 (Step S122), the simulation device 140 requests the designer to answer whether the state information Di is to be used for the image indicative of the operation of the robot model Ma (Step S123).

If there is a command for the use of the state information Di (Yes at Step S124), the simulation device 140 executes the simulation using the state information Di, and displays the operation of the robot model Ma corresponding to the state information Di on the presentation device 130 using the image to which the state information Di is reflected (Step S125).

If there is no command for the use of the state information Di (No at Step S124), the simulation device 140 executes the simulation without using the state information Di, and displays the operation of the robot model Ma corresponding to the state information Di on the presentation device 130 using the image to which state information Di is not reflected (Step S126).

In the simulation system 1, the simulation device 140 is executable of the simulation of the work area model M using the corrected control program data Dpa to which the result of the operation of the actual robot 200 is reflected. Further, even when there is the difference in the characteristics between the robot 200 and the robot model Ma, the simulation device 140 can make the operation of the robot model Ma on the image agree with the operation of the robot 200. Moreover, when correcting the work area model M, and when generating the new work area model, the simulation device 140 can generate new control program data using the corrected control program data Dpa. Since the characteristics of the actual robot are reflected to the new control program data, the new control program data may be highly accurate for the operation of the actual robot.

The simulation device 140 may be configured to repeat the processings from Step S123 to Step S126. For example, during the execution of the simulation, the simulation device 140 may request the designer to answer whether the state information Di is to be used, each time the operation of the robot model Ma corresponding to the state information Di appears, and may determine the image indicative of this operation in accordance with the designer's command.

### Modification 1

A simulation system 1A according to Modification 1 of the illustrative embodiment differs from the embodiment in that a part of the simulation computer exists on the cloud. Below, for Modification 1, the difference from the embodiment is mainly described and explanation similar to the embodiment is suitably omitted.

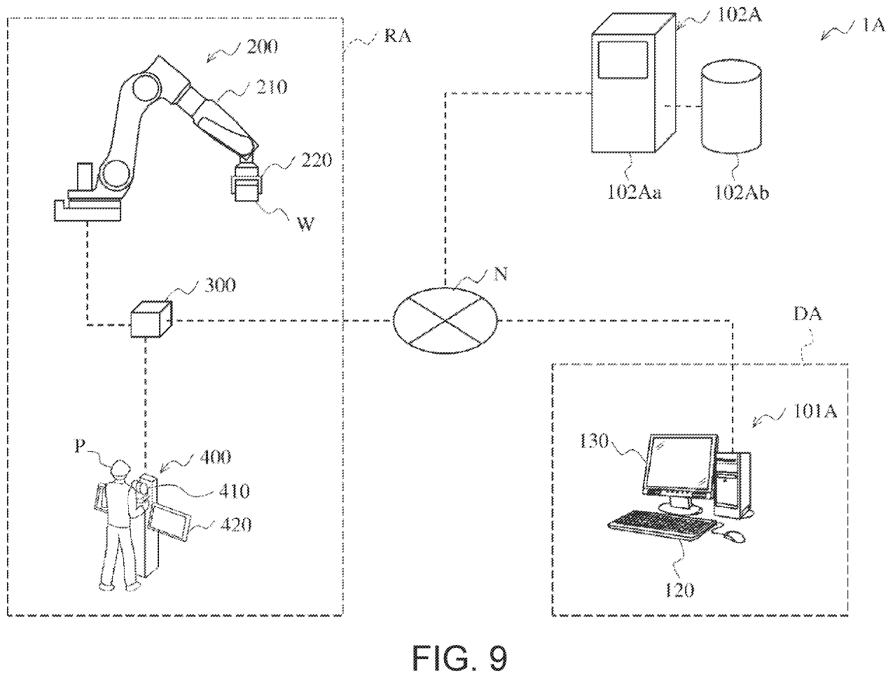

FIG. 9 is a schematic view illustrating one example of a configuration of the simulation system 1A according to Modification 1 of the illustrative embodiment. As illustrated in FIG. 9, the simulation system 1A includes a simulation terminal 101A, a server system 102A, the robot 200, the robot controller 300, and the operation I/O device 400. The simulation terminal 101A, the server system 102A, and the robot controller 300 are disposed at mutually different locations, and are connected with each other via the communication network N so as to be capable of performing data communications. For example, the simulation terminals 101A, the robot controllers 300 which control the robots 200, respectively, or both of these are connectable with the server system 102A via the communication network N. The simulation terminal 101A is one example of a terminal.

The server system 102A has a function of the simulation device 140 according to the embodiment, and for example, it can realize functions of the simulation devices 140. The server system 102A is configured to function as the simulation device 140 for one simulation terminal 101A or each of the simulation terminals 101A, and function as the simulation device 140 for one robot controller 300 or each of the robot controllers 300. The server system 102A includes a server 102Aa and a storage 102Ab. The server 102Aa may include the storage 102Ab. The server 102Aa is a computer apparatus and the storage 102Ab is a storage device. Although not limited to this configuration, in this modification, the server 102Aa has the functions of all the functional components of the simulation device 140 other than the memory part 1410, and the storage 102Ab has the function of the memory part 1410. The input part 1401 and the output part 1402 of the server 102Aa are connected with the communication network N, and communicate data etc. with the simulation terminal 101A.

The simulation terminal 101A is a computer apparatus including the input device 120 and the presentation device 130, and includes a communication interface which is connectable with the communication network N. The simulation terminal 101A may be a smart device, such as a personal computer, a smartphone, and a tablet, a personal information terminal, or other terminals. The simulation terminal 101A is capable of causing the server system 102A to perform desired processing via the communication network N. The simulation terminals 101. A can access the server system 102A, and can cause the server system 102A to perform respective desired processings.

For example, the simulation terminal 101A may be configured so that a dedicated application is installable, and may be configured to connect with the server system 102A by activating the application. The simulation terminal 101A can send a command to the server system 102A through the application to cause the server system 102A to perform various processings which are executable by the simulation device 140 according to the embodiment and output the result of each processing to a screen of this application.

For example, the simulation terminal 101A may be configured to be accessible to a website for exclusive use, and may be configured to connect with the server system 102A by logging in to the website. The simulation terminal 101A can send a command to the server system 102A on the website, and can cause the server system 102A to perform various processings which are executable by the simulation device 140 and output the result of each processing to the website.

Since the server system 102A stores various data, such as various work area models, model data, and control program data, in the storage 102Ab, the simulation terminal 1011A does not need to have a large storage capacity. Since the server system 102A performs processing which requires a large throughput, such as the establishment of the work area model, the generation of the control program data, and the execution of the simulation, the simulation terminal 101A does not need to have a large throughput. Therefore, various users can utilize the simulation system 1A by using various simulation terminals 101A. The server system 102A is executable of the simulations of various robot models using the corrected control program data Dpa of the respective robot controllers 300 by carrying out data communications with the robot controllers 300.

### Modification 2

A simulation system according to Modification 2 of the illustrative embodiment differs from Modification 1 in that at least a part of the robot controller exists on the cloud. Below, for Modification 2, the difference from the embodiment and Modification 1 is mainly described and explanation similar to the embodiment and Modification 1 is suitably omitted.

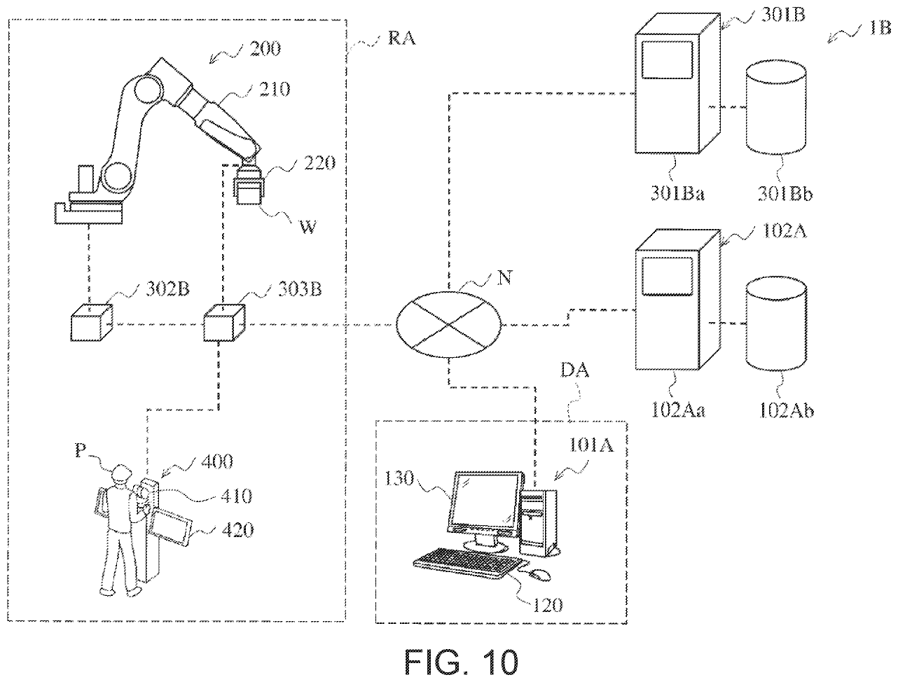

FIG. 10 is a schematic view illustrating one example of a configuration of the simulation system 1B according to Modification 2 of the illustrative embodiment. As illustrated in FIG. 10, the simulation system 1B includes the simulation terminal 101A, the server system 102A as a first server system, the robot 200, a second server system 301B, a power control device 302B, a relay device 303B, and the operation I/O device 400. The simulation terminal 101A, the first server system 102A, the second server system 301B, and the relay device 303B are disposed at mutually different locations, and are connected with each other via the communication network N so as to be capable of performing data communications with each other. For example, the relay devices 303B respectively connected to the robots 200 are connectable with the second server system 301Be via the communication network N.

The second server system 301B has the function of the computer apparatus 310 of the robot controller 300 according to the embodiment, and, for example, it can realize the function of the computer apparatuses 310. The second server system 301B is configured to function as the robot controller 300 for one robot 200 or each of the robots 200, one power control device 302B or each of the power control devices 302B, and one operation I/O device 400 or each of the operation I/O devices 400. The second server system 301E is configured to function as the robot controller 300 for the first server system 102A.

The second server system 301B includes a server 301Ba and a storage 301Bb. The server 301Ba may include the storage 301Bb. The server 301Ba is a computer apparatus and the storage 301Bb is a storage device. Although not limited to this configuration, the server 301Ba, has the functions of the processor 11 and the memory 12 of the computer apparatus 310, and the storage 301Bb includes the function of the storage 13 in this modification.

Software for controlling various robots 200 and their peripheral equipment is installed in the server 301Ba. The storage 301Bb stores information on data of various robots 200 and peripheral equipment, control program data for controlling the various robots 200 and the peripheral equipment, log data of the various robots 200 and the peripheral equipment, etc. The server 301Ba generates a command for operating the robot 200 etc. according to a command received from an external device, by using the information stored in the storage 301Bb, and transmits it to the relay device 303B of the robot 200. The server 301Ba receives the control program data Dp from the first server system 102A, stores it in the storage 30113b, and transmits the corrected control program data Dpa to the first server system 102A.

The relay device 303B includes a communication interface which is connectable with the communication network N. The relay device 303B is connectable with the second server system 301B via the communication network N. The relay device 303B is connected with a sensor etc. mounted on the robot 200, the power control device 302B, and the operation I/O device 400. The relay device 303B mediates communications between the sensor, the power control device 302B and the operation I/O device 400, and the second server system 301B. The relay device 303B may include, for example, an apparatus, such as a modem, an ONU (Optical Network Unit), and a router.

The power control device 302B is connected with an external power source, and controls electric power supplied to the robot 200 and its peripheral equipment according to a command etc. received from the second server system 301B via the relay device 303B and the communication network N. The power control device 302B may include an amplifier, an inverter, a converter, etc. The second server system 301B may be configured to transmit to the power control device 302B a command value etc. of current of each motor of each part of the robot 200 and the peripheral equipment, and may be configured to transmit a target operation command etc. of the end effector 220 of the robot 200 to the power control device 302B. In the latter case, an arithmetic unit which converts a target operation command into a command value of the current of the motor may be included in the power control device 302B, or may be a device separate from the power control device 302B, The power control device 302B may transmit a current value, a rotational amount, etc. of each motor to the second server system 301B as feedback information.

The input device 410 of the operation I/O device 400 transmits the command, information, data, etc. to the second server system 301B via the relay device 303B and the communication network N according to the inputted command. The presentation device 420 of the operation I/O device 400 presents the command, information, data, etc. which are received from the second server system 301B via the relay device 303B and the communication network N. The operation I/O device 400 can cause the second server system 301E to perform desired processing via the communication network N, The operation I/O devices 400 can access the second server system 301B, and can cause the second server system 301B to perform respective desired processings.

The operation I/O device 400 may include a computer apparatus. For example, the operation I/O device 400 may be a smart device, such as a teach pendant, a personal computer, a smartphone, and a tablet, a personal information to urinal, or other terminals.

For example, the operation I/O device 400 may be configured so that application for exclusive use may be installed, and may be configured to establish a connection between the relay device 303B and the second server system 301B by activating the application. Through the application, the operation I/O device 400 can cause the second server system 301B to perform various processings, and can cause it to output the result of each processing on the screen of the application.

For example, the operation I/O device 400 may be configured to be accessible to a dedicated website, and may be configured to establish the connection between the relay device 303B and the second server system 301B by logging in to the website. The operation I/O device 400 can cause the second server system 301B to perform various processings on the website, and can cause it to output the result of each processing to the website.

Since the second server system 301B stores various data, such as data of various robots 200, data of peripheral equipment, and control program data, in the storage 301Bb, the power control device 302B, the relay device 303B, the operation I/O device 400, etc. do not need to have large storage capacities. Since the second server system 301E performs processing which requires a large throughput, such as the motion control of the robot 200 and the correction of the control program data, the power control device 302B, the relay device 303B, the operation I/O device 400, etc. do not need to have a large throughput. Therefore, various users can cause various robots 200 to operate using the second server system 301B.

Further, in Modification 2, the operation I/O device 400 may, be configured to communicate data etc. with the second server system 301B, the relay device 303B, or both of these via the communication network N. Therefore, the robot 200 is operable by the operation I/O device 400 disposed at a location other than the robot work area. RA.

Moreover, in Modification 2, the first server system 102A may not be included. For example, instead of the simulation terminal 101A and the first server system 102A, the simulation computer 100 according to the embodiment may be included therein. The simulation computer 100 may be connected with the second server system 301B via the communication network N so as to be capable of performing data communications.

### Other Embodiments

Although the illustrative embodiment of the present disclosure is described above, the present disclosure is not limited to the embodiment and the modifications which are described above. That is, various modifications and improvements are possible within the scope of the present disclosure. For example, the scope of the present disclosure also includes the resultant of applying various modifications to the embodiment and the modifications, and a mode established by combining the components in different embodiments and modifications.

For example, in the simulation system according to this embodiment, the simulation device 140 may be connected with the robot controllers 300 which control the robots 200, respectively, via the communication network N so as to be capable of performing data communications, and may be configured to communicate data etc. with each robot controller 300.

Although the simulation system according to the above embodiment and the modifications target the industrial robot 200 and its robot model, it is not limited to this configuration. For example, the robot targeted by the simulation system may be other types of robots, such as a service robot, a medical-application robot, a drug-design robot, and a humanoid. The service robot is a robot used in various service industries, such as nursing, medical care, cleaning, security information service, rescue, cooking, and goods offering.

Moreover, examples of the respective aspects of the art of the present disclosure are given as follows. The simulator according to one aspect of the present disclosure includes the processing circuitry and the storage. The storage stores the target operation data indicative of a series of target operations, and the data relevant to the virtual robot model. The processing circuitry includes the simulator functional part that causes the robot model to operate according to the target operation data, and outputs the image data of the operating robot model to the display, and the information processing part that accepts the input of the change in the first operation that is the operation of the robot model according to the target operation data and is displayed on the display as the image, associates information indicative of the state of the robot model in the second operation, that is operation to which the change is reflected, with the information on the first operation included in the target operation data, and stores the associated information in the storage. The simulator functional part outputs the image data indicative of the second operation to the display, when causing the robot model to perform the first operation.

According to the above aspect, for example, when the target operation data is based on the operation result of the actual robot, the characteristics, such as the rigidity, inertia, and viscosity of the actual robot may be reflected on the target operation data. Between the actual robot and the robot model, characteristics difference exist, which may cause difference in their operation according to the same target operation data. The simulator accepts the input of the change in the first operation of the robot model which is indicated by the image displayed on the display and is according to the target operation data. The second operation of the robot model to which the above change is reflected may be, for example, similar operation to the actual robot which performs the first operation according to the target operation data. When causing the robot model to perform the first operation, the simulator causes the display to display the image indicative of the second operation. Therefore, the simulator is capable of causing the display to display the image of the robot model indicative of the operation similar to the actual robot, while causing the robot model to operate according to the target operation data.

In the simulator according to one aspect of the present disclosure, when causing the robot model to perform the first operation, the simulator functional part may selectively output the image data indicative of the second operation, or the image data indicative of the first operation, according to the command received from the user of the simulator. According to the above aspect, when causing the robot model to perform the first operation, the simulator may cause the display to display both of the images indicative of the second operation and the first operation. Therefore, the simulator is capable of displaying an image desired by the user.

In the simulator according to one aspect of the present disclosure, the processing circuitry may further include the building part that accepts the setup of the robot model and the virtual peripheral environment model of the robot model, and builds the robot model and the peripheral environment model, the data generating part that accepts the setup of the targeted operation of the robot model using the robot model and the peripheral environment model, generates the target operation data, and stores the target operation data in the storage, and the data update part that accepts the input of the target operation data from the external device, and updates the target operation data stored in the storage by using the accepted target operation data.

According to the above aspect, the simulator enables the establishment of the robot model and the peripheral environment model and the generation of the target operation data using the robot model and the peripheral environment model. Further, the simulator enables the input of the target operation data from the outside and the operations of the robot model and the peripheral environment model using the target operation data. For example, when the target operation data generated by the simulator is changed in the process of execution by the external device, such as the actual machine controller of the actual robot, the simulator can update the existing target operation data using the target operation data after the change. Further, the simulator enables the establishment of the robot model and the peripheral environment model using the target operation data after the update. Therefore, the simulator enables the establishment of the robot model and the peripheral environment model to which the operation result of the actual robot is reflected.

In the simulator according to one aspect of the present disclosure, the processing circuitry may further include the data transmission part that transmits the target operation data to the actual machine controller of the actual robot corresponding to the robot model via the communication network. The data update part may accept the target operation data from the actual machine controller via the communication network, and update the target operation data stored in the storage, by using the accepted target operation data. According to the above aspect, the simulator facilitates the communication of the target operation data with the actual machine controller. The simulator facilitates the update of the target operation data using the target operation data generated by the actual machine controller.

In the simulator according to one aspect of the present disclosure, the target operation data may be the teaching data for causing the actual robot corresponding to the robot model to perform operation. The data update part may accept the input of the teaching data corrected by the actual machine controller of the actual robot, and update the teaching data stored in the storage by using the corrected teaching data. According to the above aspect, the simulator can execute the simulation of the robot model using the teaching date updated by the actual machine controller.

In the simulator according to one aspect of the present disclosure, the simulator functional part may include the simulation executing part that generates the target operation command for commanding the targeted operation of the robot model according to the target operation data, operates the robot model according to the control command corresponding to the target operation command, and outputs the image data of the robot model that operates according to the control command to the display, the virtual robot controller that accepts the target operation command from the simulation executing part, generates the control command for operating each part of the robot model according to the target operation command, and sends the control command to the simulation executing part, and the converter that converts, between the simulation executing part and the virtual robot controller, the data outputted from one into the data usable on the other.

According to the above aspect, for example, the virtual robot controller may be set so as to correspond to the actual machine controller and correspond to the specifications of the actual robot, such as the type, manufacturer, etc. of the actual robot. Since the converter is included, the simulation executing part is not required to be set so as to correspond to each of the various virtual robot controllers. Therefore, the simulator is able to function by accepting the setting of the converter according to the various virtual robot controllers, which improves versatility.

The simulation system according to one aspect of the present disclosure includes the first server system including the functions of the simulator functional part and the information processing part of the processing circuitry, and the storage of the simulator according to any aspect of the present disclosure, and the terminal including the display and the inputter that accepts the input from the user of the simulator. The first server system and the terminal are connected with each other via the communication network so as to be capable of performing data communications. The first server system functions as the simulator for the terminal. According to the above aspect, even if the terminal does not have the function of the simulator, the user can perform the simulation of the robot by accessing to the first server system using the terminal. For example, the user can perform the simulation of the robot by using the terminal with lower processing ability than the first server system.

In the simulation system according to one aspect of the present disclosure, the terminal may include terminals, the terminals being connected with the first server system so as to be capable of performing mutual data communications via the communication network. The first server system may function as the simulator for each of the terminals. According to the above aspect, the users can perform the simulation of the robot by accessing the first server system using their respective terminals.

In the simulation system according to one aspect of the present disclosure, the first server system may be connected with the actual machine controller of the actual robot corresponding to the robot model via the communication network, so as to be capable of performing mutual data communications. The first server system may function as the simulator for the actual machine controller. According to the above aspect, the first server system can communicate the information with the actual machine controller corresponding to the robot model via the communication network. For example, the first server system can communicate the target operation data with the actual machine controller.

In the simulation system according to one aspect of the present disclosure, the first server system may be connected with the second server system including the calculation function and the storage function of the actual machine controller of the actual robot via the communication network, so as to be capable of performing mutual data communications. The first server system may function as the simulator for the second server system. The second server system may be connected with the power controller of the actual robot and the operation I/O device of the actual robot via the communication network so as to be capable of performing mutual data communications. The second server system may realize the calculation function and the storage function of the actual machine controller for the power controller, the operation I/O device, and the first server system.

According to the above aspect, even if two or more among the actual machine controller, the power controller, and the operation I/O device are not disposed closer to each other, the user can cause the actual robot to operate by accessing the second server system using the operation I/O device. Further, the first server system can communicate the information with the second server system via the communication network.

In the simulation system according to one aspect of the present disclosure, the second server system may be connected with the power controllers and the operation I/O devices via the communication network so as to be capable of performing mutual data communications. The second server system may include the calculation function and the storage function of the actual machine controllers, and may realize the calculation function and the storage function of the actual machine controllers for the power controllers, the operation I/O devices, and the first server system. According to the above aspect, the users can cause the target robot among the robots by accessing the second server system using their respective operation I/O devices.

The functions of the elements disclosed herein can be performed using circuitry or processing circuitry including a general-purpose processor, a dedicated processor, an integrated circuit, an ASIC (Application-Specific Integrated Circuit), conventional circuitry, and/or a combination thereof, which are configured or programmed to execute the disclosed functions. Since the processor includes transistors or other circuitry, it is considered to be the processing circuitry or the circuitry. In the present disclosure, the circuitry, the unit, or the means is hardware which performs the listed functions, or is hardware programmed to perform the listed functions. The hardware may be hardware disclosed herein, or may be other known hardware which are programmed or configured to perform the listed functions. When the hardware is the processor considered to be a kind of circuitry, the circuitry, the means, or the unit is a combination of hardware and software, and the software is used for a configuration of the hardware and/or the processor.

All the numbers used above, such as the order and the quantity are illustrated in order to concretely explain the technique of the present disclosure, and therefore, the present disclosure is not limited to the illustrated numbers. Further, the connection relationships between the components are illustrated in order to concretely explain the technique of the present disclosure, and the connection relationship which realizes the functions of the present disclosure is not limited to those relationships.

Since the scope of the present disclosure is defined by the appended claims rather than the description of this specification so that the present disclosure may be implemented in various ways without departing from the spirit of the essential features, the illustrative embodiment and modifications are illustrative but are not limitative. All the modifications of the claims and all the modifications within the scope of the claims, or the equivalents of the claims and the scope of the claims are intended to be encompassed in the appended claims.

### DESCRIPTION OF REFERENCE CHARACTERS

1, 1A, 1B Simulation System
101A Simulation Terminal (Terminal Device)
102A First Server System
110 Computer Apparatus
130 Presentation Device (display)
140 Simulation Device
140a Simulation Executing Part
140b Virtual Robot Controller
140c Converter
200 Robot (Actual Robot)
300 Robot Controller (Actual Machine Control Device)
301E Second Server System
302B Power Control Device
400 Operation Input Device
1403 Building Part
1404 Data Generating Part
1405 Simulator Functional Part
1406 Data Transmission Part
1408 Data. Update Part
1409 Processing Part (Information Processing Part)
1410 Memory Part
N Communication Network
W Object

1. A simulator, comprising:
processing circuitry; and
a storage,
wherein the storage stores target operation data indicative of a series of target operations, and data relevant to a virtual robot model,
wherein the processing circuitry includes:
simulator functional circuitry that causes the robot model to operate according to the target operation data, and outputs image data of the operating robot model to a display; and
information processing circuitry that accepts an input of a change in a first operation that is operation of the robot model according to the target operation data and is displayed on the display as an image, associates information indicative of a state of the robot model in a second operation, that is operation to which the change is reflected, with information on the first operation included in the target operation data, and stores the associated information in the storage,
wherein the simulator functional circuitry outputs image data indicative of the second operation to the display, when causing the robot model to perform the first operation.

2. The simulator of claim 1, wherein, when causing the robot model to perform the first operation, the simulator functional circuitry selectively outputs the image data indicative of the second operation, or image data indicative of the first operation, according to a command received from a user of the simulator.

3. The simulator of claim 1, wherein the processing circuitry further includes:
building circuitry that accepts a setup of the robot model and a virtual peripheral environment model of the robot model, and builds the robot model and the peripheral environment model;
data generating circuitry that accepts a setup of a targeted operation of the robot model using the robot model and the peripheral environment model, generates the target operation data, and stores the target operation data in the storage; and
data update circuitry that accepts an input of the target operation data from an external device, and updates the target operation data stored in the storage by using the accepted target operation data.

4. The simulator of claim 3, wherein the processing circuitry further includes data transmission circuitry that transmits the target operation data to an actual machine controller of the actual robot corresponding to the robot model via a communication network, and
wherein the data update circuitry accepts the target operation data from the actual machine controller via the communication network, and updates the target operation data stored in the storage, by using the accepted target operation data.

5. The simulator of claim 3, wherein the target operation data is teaching data for causing an actual robot corresponding to the robot model to perform operation, and
wherein the data update circuitry accepts an input of the teaching data corrected by an actual machine controller of the actual robot, and updates the teaching data stored in the storage by using the corrected teaching data.

6. The simulator of claim 1, wherein the simulator functional circuitry includes:
simulation executing circuitry that generates a target operation command for commanding a targeted operation of the robot model according to the target operation data, operates the robot model according to a control command corresponding to the target operation command, and outputs the image data of the robot model that operates according to the control command to the display;
virtual robot controlling circuitry that accepts the target operation command from the simulation executing circuitry, generates the control command for operating each part of the robot model according to the target operation command, and sends the control command to the simulation executing circuitry; and
converting circuitry that converts, between the simulation executing circuitry and the virtual robot controlling circuitry, data outputted from one into data usable on the other.

7. A simulation system, comprising:
a first server system including functions of the simulator functional circuitry and the information processing circuitry of the processing circuitry, and the storage of the simulator of claim 1; and
a terminal including a display and an inputter that accepts an input from the user of the simulator,
wherein the first server system and the terminal are connected with each other via a communication network so as to be capable of performing data communications, and
wherein the first server system functions as the simulator for the terminal.

8. The simulation system of claim 7, wherein the terminal includes terminals, the terminals being connected with the first server system so as to be capable of performing mutual data communications via the communication network, and
wherein the first server system functions as the simulator for each of the terminals.

9. The simulation system of claim 7, wherein the first server system is connected with an actual machine controller of an actual robot corresponding to the robot model via the communication network, so as to be capable of performing mutual data communications, and
wherein the first server system functions as the simulator for the actual machine controller.

10. The simulation system of claim 7, wherein the first server system is connected with a second server system including a calculation function and a storage function of an actual machine controller of an actual robot via the communication network, so as to be capable of performing mutual data communications,
wherein the first server system functions as the simulator for the second server system,
wherein the second server system is connected with a power controller of the actual robot and an operation inputter including an inputter and a presenter of the actual robot via the communication network so as to be capable of performing mutual data communications, and
wherein the second server system realizes the calculation function and the storage function of the actual machine controller for the power controller, the operation inputter, and the first server system.

11. The simulation system of claim 10, wherein the second server system is connected with the power controllers and the operation inputters via the communication network so as to be capable of performing mutual data communications, and
wherein the second server system includes the calculation function and the storage function of the actual machine controllers, and realizes the calculation function and the storage function of the actual machine controllers for the power controllers, the operation inputters, and the first server system.
